(19) United States
(12) Patent Application Publication
(10) Pub. No.: US 2015/0179580 A1
(43) Pub. Date: Jun. 25, 2015

(54) HYBRID INTERCONNECT STRUCTURE AND METHOD FOR FABRICATING THE SAME

(71) Applicant: UNITED MICROELECTRONICS CORP., Hsin-Chu City (TW)

(72) Inventors: Chien-Li Kuo, Hsinchu City (TW); Chun-Hung Chen, Tainan City (TW); Yung-Chang Lin, Taichung City (TW); Ming-Tse Lin, Hsinchu City (TW)

(73) Assignee: UNITED MICROELECTRONICS CORP., Hsin-Chu City (TW)

(21) Appl. No.: 14/139,879

(22) Filed: Dec. 24, 2013

(51) Int. Cl. H01L 23/532; H01L 21/768

(52) U.S. Cl. CPC H01L 23/53238; H01L 21/76846; H01L 21/76898

(57) ABSTRACT

A method for fabricating hybrid interconnect structure is disclosed. The method includes the steps of: providing a material layer; forming a through-silicon hole in the material layer; forming a patterned resist on the material layer, wherein the patterned resist comprises at least an opening for exposing the through-silicon hole; and forming a conductive layer to fill the through-silicon hole and the opening in the patterned resist.

### BACKGROUND OF THE INVENTION

1. Field of the Invention

The invention relates to a method for fabricating hybrid interconnect structures, and more particularly, to a method of fabricating through-silicon via (TSV) structures and via plugs.

2. Description of the Prior Art

A 2D integrated circuit package (2D IC package) is a single package constructed by mounting multiple semiconductor wafers/dies/chips and interconnecting them horizontally to function as a single device or system. A 3D integrated circuit package (3D IC package) or 3 dimensional stack integrated circuit package (3DS IC package) is a single integrated package constructed by stacking vertically separate semiconductor wafers/dies/chips and interconnecting them to function as a single device or system. In many designs, through-silicon via (TSV) technology enables the interconnections between the multiple semiconductor wafers/dies/chips and the resulting incorporation of substantial functionality into a relatively small package. As will be appreciated, the wafers/dies/chips may be heterogeneous. For reference, a 3D integrated circuit (3D IC) is a single wafer/die/chip having two or more layers of active electronic components integrated vertically and horizontally into a single circuit.

Recently, a different multi-die package has been developed. This type of package is sometimes referred to as a 2.5D integrated circuit package (2.5D IC package). In a 2.5D IC package, multiple wafers/dies/chips are mounted on an “interposer” structure. Multiple dies are placed on a passive silicon interposer which is responsible for the interconnections between the dies, as well as the external I/Os through the use of TSV technology. This design is superior to the 3D IC package due to lower cost and better thermal performance.

The conventional approach for fabricating interposer structures in 2.5D IC packages however requires at least two plating processes and planarizing process such as chemical mechanical polishing (CMP) process for forming an integrated structure including a TSV and a metal layer thereon, which not only reduces throughput but also increases cost substantially.

### SUMMARY OF THE INVENTION

According to a preferred embodiment of the present invention, a method for fabricating hybrid interconnect structure is disclosed. The method includes the steps of: providing a material layer;

forming a through-silicon hole in the material layer; forming a patterned resist on the material layer, wherein the patterned resist comprises at least an opening for exposing the through-silicon hole; and forming a conductive layer to fill the through-silicon hole and the opening in the patterned resist.

According to another aspect of the present invention, a hybrid interconnect structure is disclosed. The hybrid interconnect structure includes: a through-silicon hole in a material layer; a vertical conductive portion in the through-silicon hole; a horizontal conductive portion on the vertical portion and the material layer; a passivation layer on the horizontal portion and at least a portion of the material layer; and planar layer on the material layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-5 illustrate a method for fabricating hybrid interconnect structure according to a preferred embodiment of the present invention.

FIGS. 6-10 illustrate a method for fabricating via plug structure according to an embodiment of the present invention.

### DETAILED DESCRIPTION

Referring to FIGS. 1-5, FIGS. 1-5 illustrate a method for fabricating hybrid interconnect structure according to a preferred embodiment of the present invention. As shown in FIG. 1, a material layer, such as a substrate 12 is first provided, in which the substrate 12 could be composed of monocrystalline silicon, gallium arsenide (GaAs), silicon on insulator (SOI) layer, epitaxial layer, or other known semiconductor material, but not limited thereto. Preferably, the hybrid interconnect structure is preferably utilized as a through silicon interposer (TSI), hence no active device is formed on the substrate 12.

Next, a photo-etching process could be carried out to form at least a through-silicon hole 14 in the substrate 12, and a liner 16 and a barrier layer 18 are formed sequentially on the top surface of the substrate 12 and sidewalls and bottom of the through-silicon hole 14. The liner 16 is preferably served as an isolation between the TSV structure and the surrounding substrate such that the two elements would not be connected directly. The liner 16 is preferably consisting of silicon oxide or silicon nitride, and could also be composed of a single or composite layer. The barrier layer 18 is preferably selected from a group consisting of Ta, TaN, Ti, and TiN, but not limited thereto.

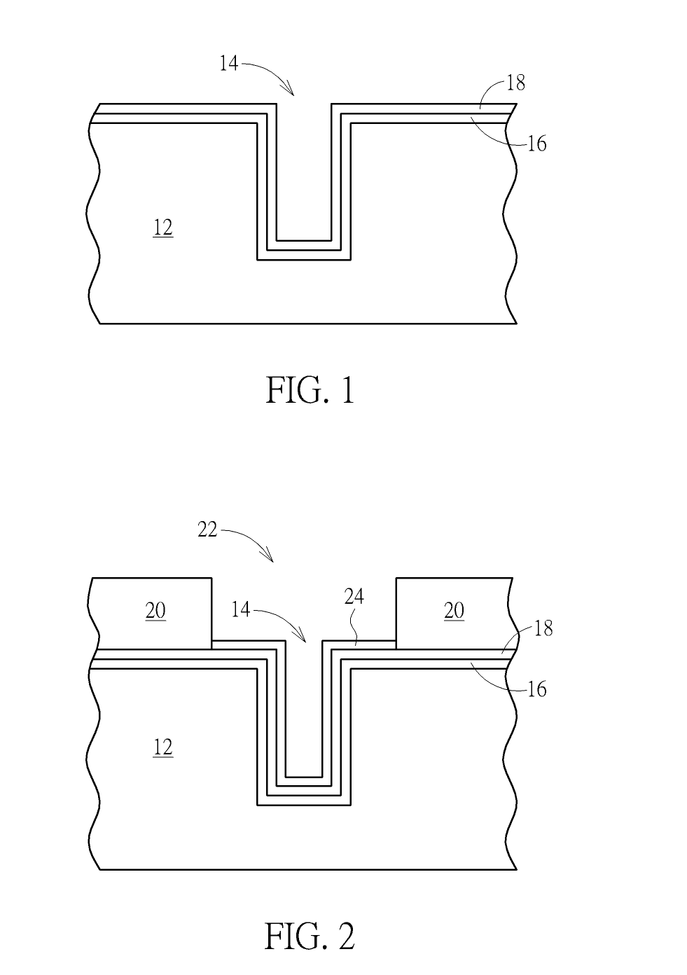

As shown in FIG. 2, a patterned resist 20 is then formed on the barrier layer 18, in which the patterned resist 20 includes at least an opening 22 for exposing the through-silicon hole 14. An electroless process is conducted thereafter to form a seed layer 24 on the barrier layer 18 not covered by the patterned resist 20.

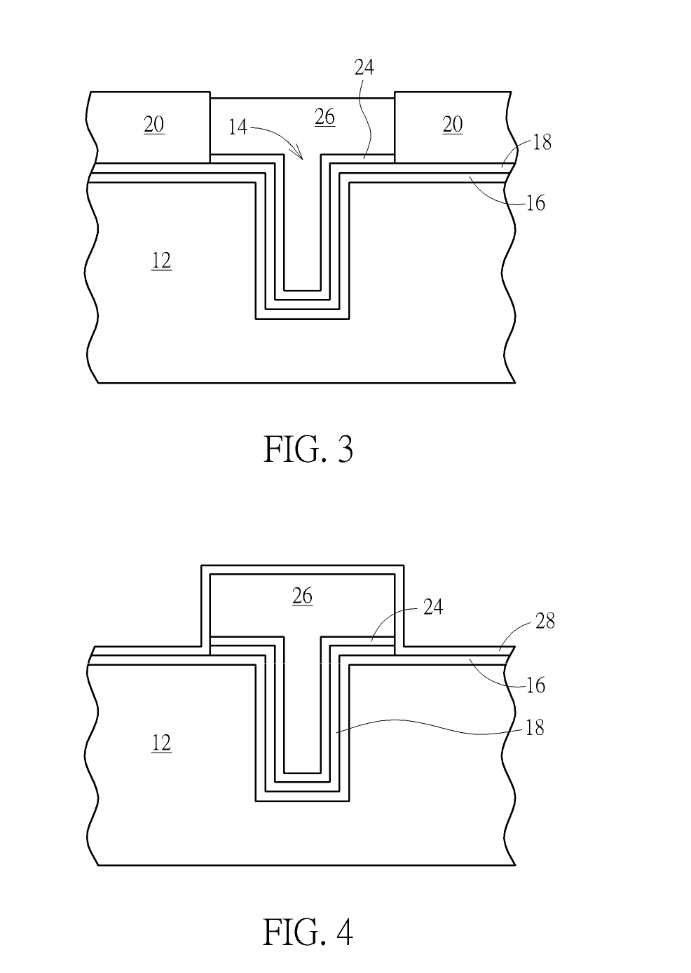

Next, as shown in FIG. 3, an electrochemical plating (ECP) process is performed to form a conductive layer 26 on the seed layer 24 for filling the through-silicon hole 14 and the opening 22 in the patterned resist 20. The ECP process is preferably accomplished by an electroless process, but not limited thereto. The seed layer 24 and the conductive layer 26 are preferably composed of copper, but could also be composed of conductive materials other than copper, which is also within the scope of the present invention.

As shown in FIG. 4, after stripping the patterned resist 20, a dry etching process is performed to remove the barrier layer 18 on the substrate 12 not covered by the conductive layer 26, and a passivation layer 28 is deposited on the conductive layer 26 and the liner 16 not covered by the conductive layer 26. The passivation layer 28 is preferably composed of silicon nitride, but not limited thereto.

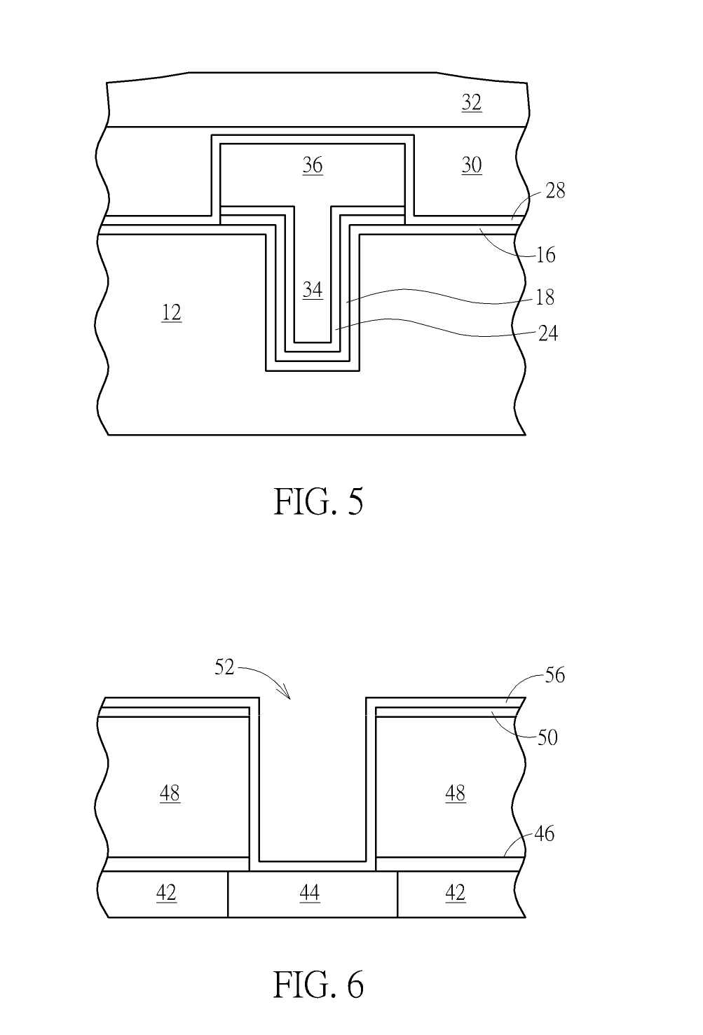

After depositing the passivation layer 28, as shown in FIG. 5, a first planar layer 30 and a second planar layer 32 are formed sequentially on the passivation layer. According to a preferred embodiment of the present invention, the first planar layer 30 is consisting of spin-on-glass (SOG) film and the second planar layer 32 is consisting of polyethylene oxide (PEOX), but not limited thereto. By following the aforementioned steps as disclosed, only one plating process is needed throughout the entire fabrication process and planarizing steps such as CMP process could also be eliminated, which thereby increasing throughput and reducing cost of the fabrication substantially. This completes the fabrication of a TSV structure, or a hybrid interconnect structure according to a preferred embodiment of the present invention.

It should be noted that from the aforementioned fabrication process, a hybrid interconnect structure is further disclosed. The hybrid interconnect structure preferably includes a through-silicon hole 14 in a substrate 12, a vertical conductive portion 34 in the through-silicon hole 14, a horizontal conductive portion 36 on the vertical conductive portion 34 and the substrate 12, a passivation layer 28 on the horizontal conductive portion 36 and at least a portion of the substrate 12, a first planar layer 30 on the substrate 12, and a second planar layer 32 on the first planar layer 30.

According to a preferred embodiment of the present invention, the vertical conductive portion 34 and the horizontal conductive portion 36 are both consisting of copper, the passivation layer 28 is composed of silicon nitride, the first planar layer 30 is composed of SOG film, and the second planar layer 32 is composed of PEOX.

In addition to the aforementioned embodiment for fabricating TSV, the aforementioned method could also be applied to the fabrication of metal interconnect structures. As shown in FIGS. 6-10, FIGS. 6-10 illustrate a method for fabricating via plug structure according to another embodiment of the present invention. As shown in FIG. 6, a material layer, such as a dielectric layer 42 is provided, in which a metal layer 44 could be formed and embedded within the dielectric layer 42. The metal layer 44 could be electrically connected to a gate structure or other devices formed on a substrate (not shown) beneath the dielectric layer 42 and the metal layer 44, and the fabrication of the metal layer 44 could be accomplished by typical metal interconnect fabrication processes. As such processes are well known to those skilled in the art, the details of which are not explained herein for the sake of brevity.

After the metal layer 44 is formed, an etching stop layer 46, another dielectric layer 48, and a cap layer 50 are formed on the dielectric layer 48. The etching stop layer 46 is consisting of silicon nitride, the dielectric layer 48 is consisting of phosphosilicate glass (PSG), and the cap layer 50 is consisting of silicon oxynitride, but not limited thereto.

Next, a photo-etching process could be carried out to form at least a through-silicon hole 52 in the dielectric layer 48, and a chemical vapor deposition (CVD) is conducted to form a barrier layer 56 on the top surface of the cap layer 50 and sidewalls and bottom of the through silicon hole 52. The barrier layer 56 is preferably selected from a group consisting of Ta, TaN, Ti, and TiN, but not limited thereto. Similar to the aforementioned embodiment, a liner (not shown) consisting of silicon oxide or silicon nitride could be formed selectively between the barrier layer 56, the cap layer 50, and the dielectric layer 48, which is also within the scope of the present invention.

As shown in FIG. 7, a patterned resist 58 is then formed on the barrier layer 56, in which the patterned resist 58 includes at least an opening 60 for exposing the through-silicon hole 52. An electroless process is conducted thereafter to form a seed layer 62 on the barrier layer 56 not covered by the patterned resist 58.

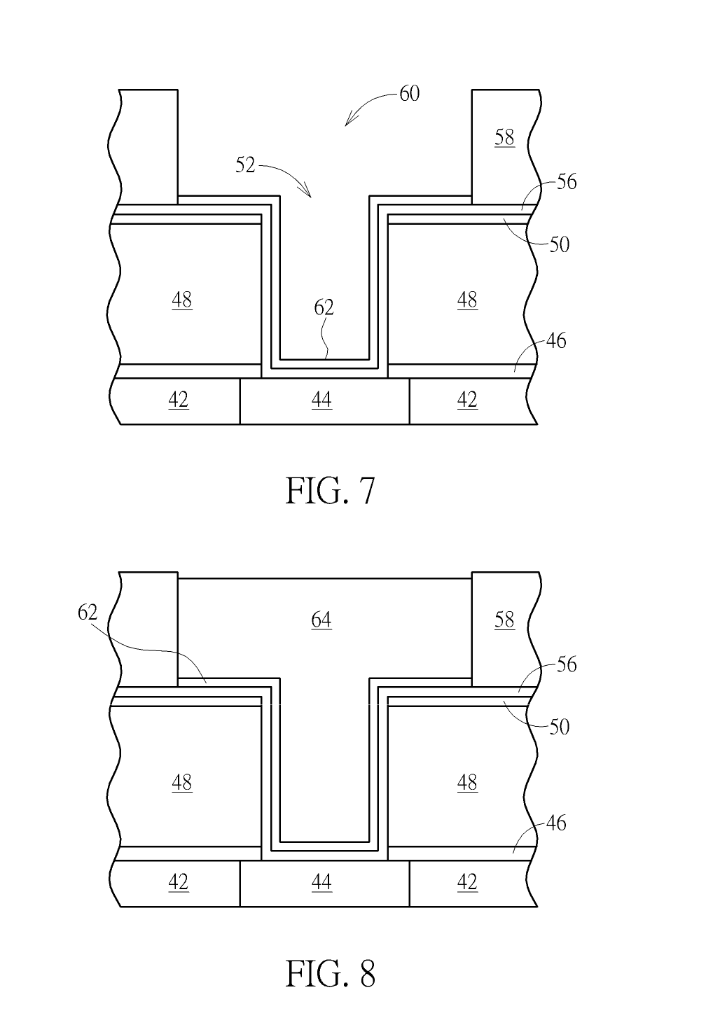

Next, as shown in FIG. 8, an electrochemical plating (ECP) process is conducted to form a conductive layer 64 on the seed layer 62 for filling the through-silicon hole 52 and the opening 60 in the patterned resist 58. The ECP process is preferably accomplished by an electroless process, but not limited thereto. The seed layer 62 and the conductive layer 64 are preferably composed of copper, but could also be composed of conductive materials other than copper, which is also within the scope of the present invention.

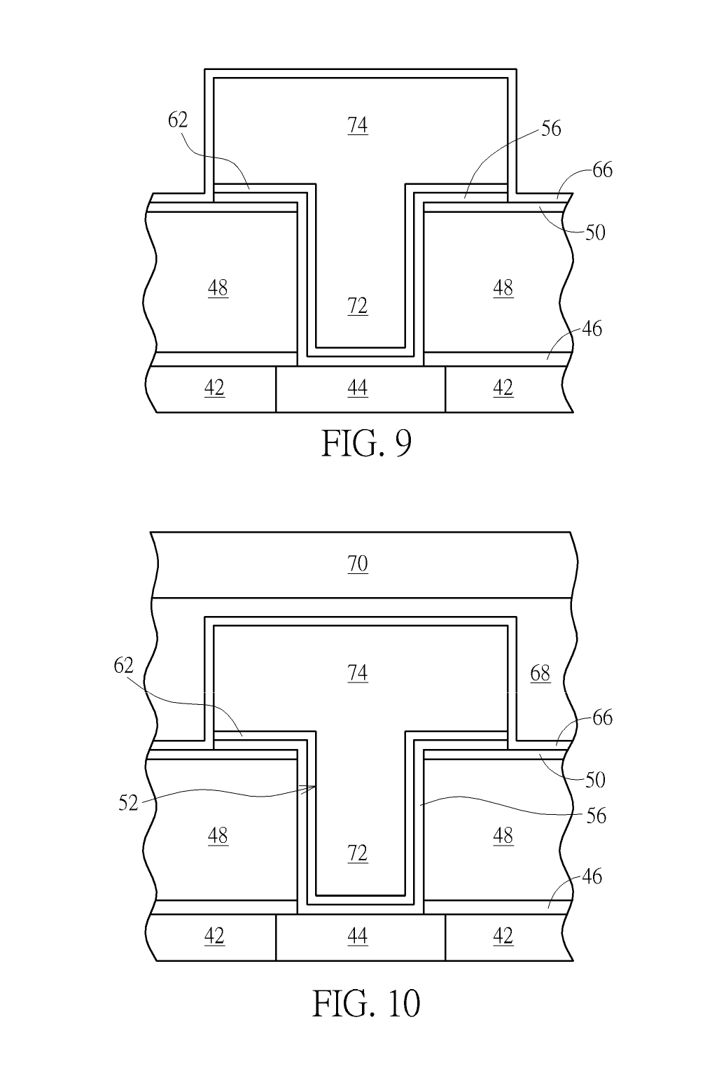

As shown in FIG. 9, after stripping the patterned resist 58, a dry etching process is performed to remove the barrier layer 56 on the dielectric layer 50 not covered by the conductive layer 64, and a passivation layer 66 is deposited on the conductive layer 64 and the liner 54 not covered by the conductive layer 64. The passivation layer 66 is preferably composed of silicon nitride, but not limited thereto.

After depositing the passivation layer 66, as shown in FIG. 10, a first planar layer 68 and a second planar layer 70 are formed sequentially on the passivation layer 66. According to a preferred embodiment of the present invention, the first planar layer 68 is consisting of spin-on-glass (SOG) film and the second planar layer 70 is consisting of polyethylene oxide (PEOX), but not limited thereto. This completes the fabrication of a TSV structure, or a hybrid interconnect structure according to another embodiment of the present invention.

It should be noted that from the aforementioned fabrication process, a hybrid interconnect structure is further disclosed. The hybrid interconnect structure preferably includes a through-silicon hole 52 in a dielectric layer 48, a vertical conductive portion 72 in the through-silicon hole 52, a horizontal conductive portion 74 on the vertical conductive portion 72 and the dielectric layer 48, a passivation layer 66 on the horizontal conductive portion 74 and at least a portion of the dielectric layer 48, a first planar layer 68 on the dielectric layer 48, and a second planar layer 70 on the first planar layer 68.

According to a preferred embodiment of the present invention, the vertical conductive portion 72 and the horizontal conductive portion 74 are both consisting of copper, the passivation layer 66 is composed of silicon nitride, the first planar layer 68 is composed of SOG film, and the second planar layer 70 is composed of PEOX.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating hybrid interconnect structure, comprising:
providing a material layer;
forming a through-silicon hole in the material layer;
forming a patterned resist on the material layer, wherein the patterned resist comprises at least an opening for exposing the through-silicon hole; and
forming a conductive layer to fill the through-silicon hole and the opening in the patterned resist.

2. The method of claim 1, wherein the material layer comprises a substrate.

3. The method of claim 1, wherein the material layer comprises a dielectric layer.

4. The method of claim 1, further comprising:
forming a liner on the material layer and a bottom and sidewalls of the through-silicon hole;
forming a barrier layer on the liner;
forming the patterned resist on the barrier layer;
forming the conductive layer on the barrier layer to fill the through-silicon hole and the opening in the patterned resist;
removing the patterned resist;
removing the barrier layer on the material layer;
depositing a passivation layer on the conductive layer and the material layer;
forming a first planar layer on the passivation layer; and
forming a second planar layer on the first planar layer.

5. The method of claim 4, wherein the liner comprises oxide.

6. The method of claim 4, wherein the barrier layer is selected from a material consisting of Ta, TaN, Ti, and TiN.

7. The method of claim 4, further comprising performing an electroless deposition for forming the conductive layer in the through-silicon hole and the opening.

8. The method of claim 4, further comprising performing a dry etching process for removing the barrier layer.

9. The method of claim 4, wherein the passivation layer comprises silicon nitride.

10. The method of claim 4, wherein the first planar layer comprises spin-on-glass (SOG) film.

11. The method of claim 4, wherein the second planar layer comprises polyethylene oxide (PEOX).

12. The method of claim 1, wherein the conductive layer comprises copper.

13. A hybrid interconnect structure, comprising:
a through-silicon hole in a material layer;
a vertical conductive portion in the through-silicon hole;
a horizontal conductive portion on the vertical conductive portion and the material layer;
a passivation layer on the horizontal conductive portion and at least a portion of the material layer; and
a first planar layer on the material layer.

14. The hybrid interconnect structure of claim 13, wherein the material layer comprises a substrate.

15. The hybrid interconnect structure of claim 13, wherein the material layer comprises a dielectric layer.

16. The hybrid interconnect structure of claim 13, wherein the vertical conductive portion and the horizontal conductive portion comprise copper.

17. The hybrid interconnect structure of claim 13, wherein the passivation layer comprises silicon nitride.

18. The hybrid interconnect structure of claim 13, wherein the first planar layer comprises spin-on-glass (SOG) film.

19. The hybrid interconnect structure of claim 13, further comprising a second planar layer on the first planar layer.

20. The hybrid interconnect structure of claim 19, wherein the second planar layer comprises polyethylene oxide (PEOX).
